(19) United States
(12) Patent Application Publication
(10) Pub. No.: US 2016/0265107 A1
(43) Pub. Date: Sep. 15, 2016

(54) SUBSTRATE HOLDER AND SUBSTRATE PROCESSING APPARATUS

(71) Applicant: Tokyo Electron Limited, Tokyo (JP)

(72) Inventor: Masami OIKAWA, Iwate (JP)

(21) Appl. No.: 15/055,737

(22) Filed: Feb. 29, 2016

(30) Foreign Application Priority Data
Mar. 12, 2015 (JP) 2015-049379

(51) Int. Cl. C23C 16/455; C23C 16/458; C23C 16/50; H01L 21/687

(52) U.S. Cl. CPC C23C 16/455; H01L 21/68771; H01L 21/68785; C23C 16/458; C23C 16/50

(57) ABSTRACT

A substrate holder holds a stack of substrates to be plasma-processed, and includes a ring-shaped part to be placed between adjacent substrates each of which includes a process surface to be plasma-processed and a non-process surface opposite from the process surface. The ring-shaped part includes a facing surface that faces the process surface of one of the adjacent substrates, and a protrusion formed along the outer periphery of the facing surface.

### CROSS-REFERENCE TO RELATED APPLICATION

The present application is based upon and claims the benefit of priority of Japanese Patent Application No. 2015-049379, filed on Mar. 12, 2015, the entire contents of which are incorporated herein by reference.

### BACKGROUND OF THE INVENTION

1. Field of the Invention

An aspect of this disclosure relates to a substrate holder and a substrate processing apparatus.

2. Description of the Related Art

There exists a vertical substrate processing apparatus that performs a film deposition process on multiple wafers at once (batch processing). In a vertical substrate processing apparatus, a wafer boat holding a stack of wafers is placed in a process chamber, and a process gas is supplied from a gas supply unit to the wafers to perform a film deposition process.

For example, Japanese Laid-Open Patent Publication No. 2010-132958 discloses a vertical substrate processing apparatus that includes a wafer boat for holding multiple wafers in a stack. The wafer boat includes rings each of which has a circular hole and is disposed just above one of the wafers. In the wafer boat of the disclosed vertical substrate processing apparatus, the rings are arranged such that the diameter of the circular hole of the rings gradually increases from the lower end to the upper end of the wafer boat.

However, with the configuration of Japanese Laid-Open Patent Publication No. 2010-132958, plasma directly acts on the outer periphery of each wafer and therefore a film formed on the outer periphery of the wafer may shrink. Accordingly, it is necessary to further improve the in-plane uniformity in film thickness.

### SUMMARY OF THE INVENTION

In an aspect of this disclosure, there is provided a substrate holder for holding a stack of substrates to be plasma-processed. The substrate holder includes a ring-shaped part to be placed between adjacent substrates each of which includes a process surface to be plasma-processed and a non-process surface opposite from the process surface. The ring-shaped part includes a facing surface that faces the process surface of one of the adjacent substrates, and a protrusion formed along the outer periphery of the facing surface.

### BRIEF DESCRIPTION OF THE DRAWINGS

FIG. 1 is a schematic vertical cross-sectional view of a substrate processing apparatus according to an embodiment;

FIG. 2 is a schematic horizontal cross-sectional view of the substrate processing apparatus of FIG. 1;

FIG. 3 is a drawing illustrating an exemplary wafer boat;

FIG. 4 is a schematic side view of an exemplary ring-shaped part;

FIG. 5 is a schematic perspective view of an exemplary ring-shaped part;

FIG. 6 is a graph illustrating measurement results of the thickness of an SiO₂ film formed on a wafer placed in the uppermost position in a wafer boat;

FIG. 7 is a graph illustrating measurement results of the thickness of an SiO₂ film formed on a wafer placed in the middle position in a wafer boat; and

FIG. 8 is a graph illustrating measurement results of the thickness of an SiO₂ film formed on a wafer placed in the lowermost position in a wafer boat.

### DESCRIPTION OF THE PREFERRED EMBODIMENTS

Embodiments of the present invention are described below with reference to the accompanying drawings. In the specification and the drawings of the present application, the same reference number is assigned to components having substantially the same function, and repeated descriptions of those components are omitted.

### Configuration of Substrate Processing Apparatus

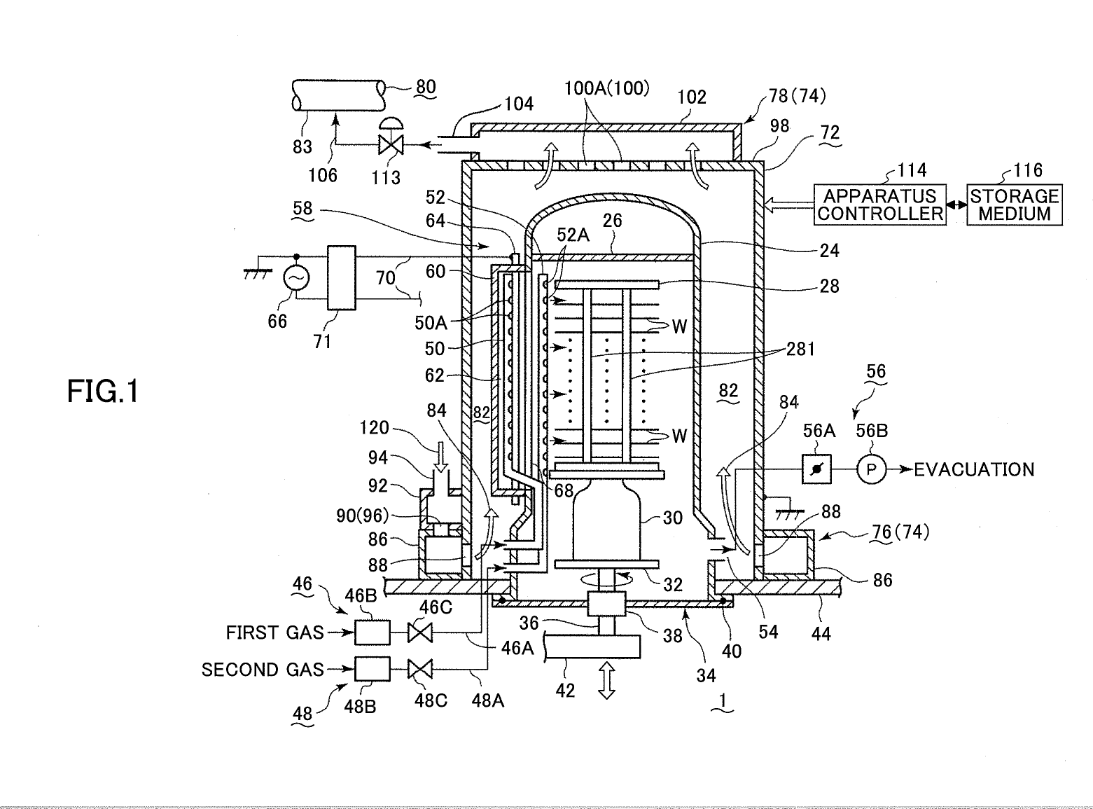

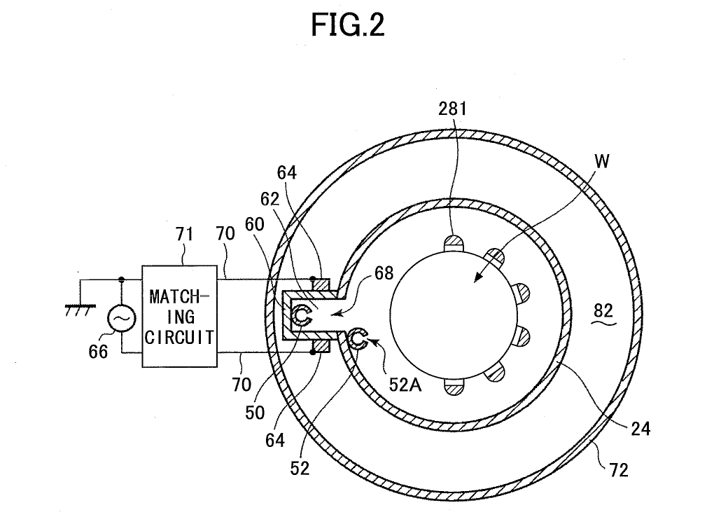

An exemplary substrate processing apparatus including a substrate holder of an embodiment is described. FIG. 1 is a schematic vertical cross-sectional view of a substrate processing apparatus 1 according to an embodiment. FIG. 2 is a schematic horizontal cross-sectional view of the substrate processing apparatus 1 of FIG. 1.

As illustrated by FIGS. 1 and 2, the substrate processing apparatus 1 includes a process chamber 24 that is oriented in the vertical direction and shaped like a vertically-long cylinder. The process chamber 24 has a ceiling and has an opening (lower-end opening) at the lower end. The process chamber 24 may be comprised of, for example, quartz. A ceiling board 26 comprised of quartz is provided in the process chamber 24 at a position near its upper end to seal the upper internal space of the process chamber 24. A lower part of the process chamber 24 has an inside diameter that is slightly greater than the inside diameter of other parts of the process chamber 24 to improve the exhaust characteristic, and the bottom of the lower part is open. For example, a cylindrical manifold comprised of stainless steel may be connected to the lower part.

The substrate processing apparatus 1 also includes a wafer boat 28 that is comprised of quartz and can hold multiple semiconductor wafers W in a stack. The semiconductor wafer W is an example of objects to be processed, and the wafer boat 28 is an example of a substrate holder. The wafer boat 28 is movable upward and downward, and can be carried into and out of the process chamber 24 via the lower-end opening. In the present embodiment, columns 281 of the wafer boat 28 are configured to be able to support, for example, 50 to 150 wafers W having a diameter of 300 mm and stacked at substantially the same pitch.

The wafer boat 28 is placed on a table 32 via a heat-insulating tube 30 comprised of quartz. The table 32 is supported by a rotary shaft 36 passing through a lid 34 that is comprised of, for example, stainless steel and for opening and closing the lower-end opening of the process chamber 24. For example, a magnetic fluid seal 38 is provided on a pass-through part of the rotary shaft 36 passing through the lid 34 to seal the pass-through part and to rotatably support the rotary shaft 36. Also, a seal 40 such as an O-ring is provided between the periphery of the lid 34 and the lower end of the process chamber 24 to seal the process chamber 24.

The rotary shaft 36 is attached to an end of an arm 42 supported on an elevating mechanism (not shown) such as a boat elevator so that the wafer boat 28 can be moved up and down together with the lid 34 and can be carried into and out of the process chamber 24. Alternatively, the table 32 may be fixed to the lid 34, and the wafers W may be processed without rotating the wafer boat 28. The lower end of the process chamber 24 is attached to and supported by a base plate 44 comprised of, for example, stainless steel.

A first gas supply unit 46 is provided to supply a first gas to be activated by plasma into the process chamber 24, and a second gas supply unit 48 is provided to supply a second gas into the process chamber 24. The first gas supply unit 46 includes a first gas nozzle 50 comprised of a quartz tube. The first gas nozzle 50 passes through a lower side wall of the process chamber 24 into the process chamber 24, and is then bent to extend upward. The first gas nozzle 50 is a dispersion gas nozzle where multiple (many) gas discharge holes 50A are formed at predetermined intervals along its longitudinal direction, and is configured such that the first gas can be substantially evenly discharged in the horizontal direction from the gas discharge holes 50A.

Similarly, the second gas supply unit 48 includes a second gas nozzle 52 comprised of a quartz tube. The second gas nozzle 52 passes through a lower side wall of the process chamber 24 into the process chamber 24, and is then bent to extend upward. The second gas nozzle 52 is a dispersion gas nozzle where multiple (many) gas discharge holes 52A are formed at predetermined intervals along its longitudinal direction, and is configured such that the second gas can be substantially evenly discharged in the horizontal direction from the gas discharge holes 52A. Flow controllers 46B and 48A such as mass flow controllers for controlling gas flow rates and on-off valves 46C and 48C are provided on gas flow paths 46A and 48A connected to the first and second gas nozzles 50 and 52, respectively.

Although only the first gas supply unit 46 for supplying the first gas and the second gas supply unit 48 for supplying the second gas are illustrated in FIGS. 1 and 2, additional gas supply units may be provided when more than two types of gases are used. Also, although not shown in FIGS. 1 and 2, a purge gas supply unit for supplying a purge gas such as N₂ and a cleaning gas supply unit for supplying a cleaning gas such as a hydrogen fluoride (HF) gas used to remove an unnecessary film may also be provided.

An evacuation opening 54 is formed in the lower side wall of the process chamber 24. An evacuation system 56 including a pressure-regulating valve 56A and a vacuum pump 56B is connected to the evacuation opening 54 to evacuate the atmosphere in the process chamber 24 and maintain the process chamber 24 at a predetermined pressure.

An activation unit 58 is provided in the process chamber 24 along its longitudinal direction. The activation unit 58 activates the first gas by plasma generated by high-frequency power. As illustrated also in FIG. 2, the activation unit 58 includes a plasma formation box 62 formed by a plasma partition wall 60 provided along the longitudinal direction of the process chamber 24, plasma electrodes 64 provided on the plasma partition wall 60 along its longitudinal direction, and a high-frequency power supply 66 connected to the plasma electrodes 64.

More specifically, the plasma formation box 62 is formed by forming a vertically-long opening 68 with a predetermined width in the side wall of the process chamber 24, and covering the opening 68 with the vertically-long plasma partition wall 60 formed on the outside of the side wall. The plasma partition wall 60 is comprised of, for example, quartz, has a cross section with a square-bracket shape, and is welded onto the outer side wall of the process chamber 24.

As a result, a part of the side wall of the process chamber 24 protrudes outward, and the plasma formation box 62 having a square-bracket shaped cross section is formed. One side of the plasma formation box 62 is the opening 68 that communicates with the process space of the process chamber 24. That is, the space inside of the plasma partition wall 60 is a plasma formation area and communicates with the process space of the process chamber 24. The opening 68 has a length in the vertical direction that is sufficient to cover all the wafers W held in the wafer boat 28 in the height direction. A pair of plasma electrodes 64 are provided on the outer sides of the plasma partition wall 60 to face each other. The plasma electrodes 64 extend the entire length of the plasma formation box 62.

The plasma electrodes 64 are connected to power supply lines 70 that are connected via a matching circuit 71 for impedance matching to the high-frequency power supply 66 for plasma generation. Plasma is formed in the plasma formation box 62 by the high-frequency power supplied from the high-frequency power supply 66. The frequency of the high-frequency power supply 66 may be, for example, 13.56 MHz. However, the frequency of the high-frequency power supply 66 is not limited to 13.56 MHz, and any frequency between 4 MHz and 27.12 MHz may be used.

The first gas nozzle 50 extending upward in the process chamber 24 is bent in the middle to extend outward in the radial direction of the process chamber up to the innermost position (a position farthest from the center of the process chamber 24) in the plasma formation box 62, and is then bent again to extend upward in an upright position along the innermost wall of the plasma formation box 62. With the above configuration, the first gas discharged from the gas discharge holes 50A of the first gas nozzle 50 while the high-frequency power supply 66 is turned on is activated by plasma, and diffuses and flows toward the center of the process chamber 24. Instead of forming the first gas nozzle 50 to pass through the side wall of the process chamber 24, the first gas nozzle 50 may be formed to directly pass through the bottom of the plasma partition wall 60.

The second gas nozzle 52 is disposed in an upright position at an edge of the opening 68 of the process chamber 24. The second gas is discharged from the gas discharge holes 52A of the second gas nozzle 52 toward the center of the process chamber 24. A shield housing 72 and a cooling mechanism 74 are provided outside of the process chamber 24 configured as described above. The cooling mechanism 74 supplies a cooling gas into the shield housing 72 during plasma processing. The shield housing 72 has, for example, a cylindrical shape and surrounds the entire process chamber 24 including its upper end. The shield housing 72 is grounded and comprised of a metal such as aluminum or stainless steel, and blocks the high frequency radiation from the activation unit 58 to prevent it from leaking into the outside.

The lower end of the shield housing 72 is connected to the base plate 44 to also prevent the leakage of the high-frequency radiation from the bottom of the shield housing 72. The shielding ratio (specific conductivity x relative permeability x thickness) of the shield housing 72 is preferably as high as possible. For example, when SUS 304 (a type of stainless steel) is used for the shield housing 72, the thickness of SUS 304 is preferably greater than or equal to 1.5 mm. Also, when the diameter of the process chamber 24 housing the wafers W with a diameter of 300 mm is about 450 mm, the diameter of the shield housing 72 is about 600 mm.

The cooling mechanism 74 attached to the shield housing 72 includes an inlet header 76 provided at the lower end of the shield housing 72 to introduce a cooling gas, and an exhaust header 78 provided at the upper end of the shield housing 72 to discharge the atmosphere in the shield housing 72. The cooling mechanism 74 causes the cooling gas to flow through a space 82 between the shield housing 72 and the process chamber 24 as indicated by an arrow 84. The exhaust header 78 is connected to an exhaust source 80. The exhaust source 80 is implemented by, for example, a factory duct 83 for discharging gases from apparatuses including the substrate processing apparatus 1 installed in a clean room. A large exhaust fan (not shown) is provided downstream of the factory duct 83 to discharge gases from the entire factory.

The inlet header 76 includes a gas flow duct 86 provided on the side wall of the shield housing 72 along its circumference, gas flow holes 88 formed in the side wall of the shield housing 72 at predetermined intervals along its circumference, and gas inlets 90 formed in the gas flow duct 86 to introduce the cooling gas. In this example, the gas flow duct 86 has a substantially-rectangular cross section, and is formed in a ring to surround the lower end of the shield housing 72.

A pair of gas inlets 90 are formed in the ceiling of the gas flow duct 86 to face each other across the diameter of the shield housing 72. In this example, the gas flow holes 88 have a rectangular shape, and four gas flow holes 88 are formed at regular intervals along the circumference of the shield housing 72. With this configuration, the cooling gas introduced via the two gas inlets 90 into the gas flow duct 86 flows along the gas flow duct 86 and then flows via the rectangular gas flow holes 88 into the shield housing 72.

In this case, to allow the cooling gas to flow evenly, each of the gas inlets 90 is preferably formed at a midpoint between adjacent gas flow holes 88. The number of the gas flow holes 88 is not limited to four, and may be two, three, five or more. Also, the gas flow holes 88 may be arranged in a ring as in a punching metal. Further, to improve the high-frequency shielding effect, a punching metal may be attached to the gas flow holes 88.

A cooling gas guiding duct 92 having a semicircular (or arc) shape is provided over the gas inlets 90. A gas inlet 94 is provided in the center of the cooling gas guiding duct 92. Also, openings 96 communicating with the gas inlets 90 are formed at the ends of the cooling gas guiding duct 92. In the present embodiment, clean air in the clean room that is maintained at 23 to 27° C. is used as the cooling gas. The cooling gas or the clean air introduced via the gas inlets 90 flows through the cooling gas guiding duct 92, and flows via the openings 96 and the gas inlets 90 into the ring-shaped gas flow duct 86. Then, the cooling gas flows in two directions in the gas flow duct 86, and flows via the gas flow holes 88 into the shield housing 72. In practice, an air supply channel (not shown) is connected to the gas inlet 94, and the clean air at the same temperature as the ambient temperature of the clean room is supplied from the air supply channel via the gas inlet 94 into the cooling gas guiding duct 92.

Alternatively, the cooling gas guiding duct 92 may be omitted, and the cooling air may be directly introduced into the gas flow duct 86 through the two gas inlets 90. Also, more than two gas inlets 90 may be formed in the gas flow duct 86.

The exhaust header 78 provided at the upper end of the shield housing 72 includes a gas flow hole 100 formed in an end plate 98 closing the upper end of the shield housing 72, an exhaust box 102 formed to surround the gas flow hole 100, a gas exhaust port 104 provided on the exhaust box 102, and an exhaust channel 106 connecting the gas exhaust port 104 and the factory duct 83 that implements the exhaust source 80.

The end plate 98 functions as a ceiling board of the shield housing 72, and is also made of a metal plate such as a stainless steel plate that can shield high-frequency radiation. The gas flow hole 100 in the end plate 98 is formed by arranging multiple punch holes 100A with a small diameter in order to maintain the capability to shield high-frequency radiation while allowing the cooling gas to flow upward into the exhaust box 102. A punching metal having multiple holes formed in its central area may be used as the end plate 98. Alternatively, the gas flow hole 100 may be formed as a single hole having a large diameter, and a punching metal may be attached to the gas flow hole 100.

The cooling gas flows through the punch holes 100A into the exhaust box 102, and then flows through the gas exhaust port 104 toward the factory duct 83. Although the gas exhaust port 104 is provided on the side wall of the exhaust box 102 in FIG. 1, the gas exhaust port 104 may instead be provided on the upper wall of the exhaust box 102 so that the cooling gas is discharged upward. A flow control valve 113 is provided on the exhaust channel 106 to control the exhaust flow rate.

The entire operation of the substrate processing apparatus 1 is controlled by an apparatus controller 114 implemented by, for example, a computer. For example, the apparatus controller 114 starts and stops supply of gases, sets the power level of the high-frequency power supply 66, turns on and off the high-frequency power supply 66, and sets process pressures. The apparatus controller 114 includes or connected to a computer-readable storage medium 116 that stores a program for controlling the entire operation of the substrate processing apparatus 1. Examples of the storage medium 116 include a flexible disk, a compact disk (CD), a hard disk, a flash memory, and a digital versatile disk (DVD).

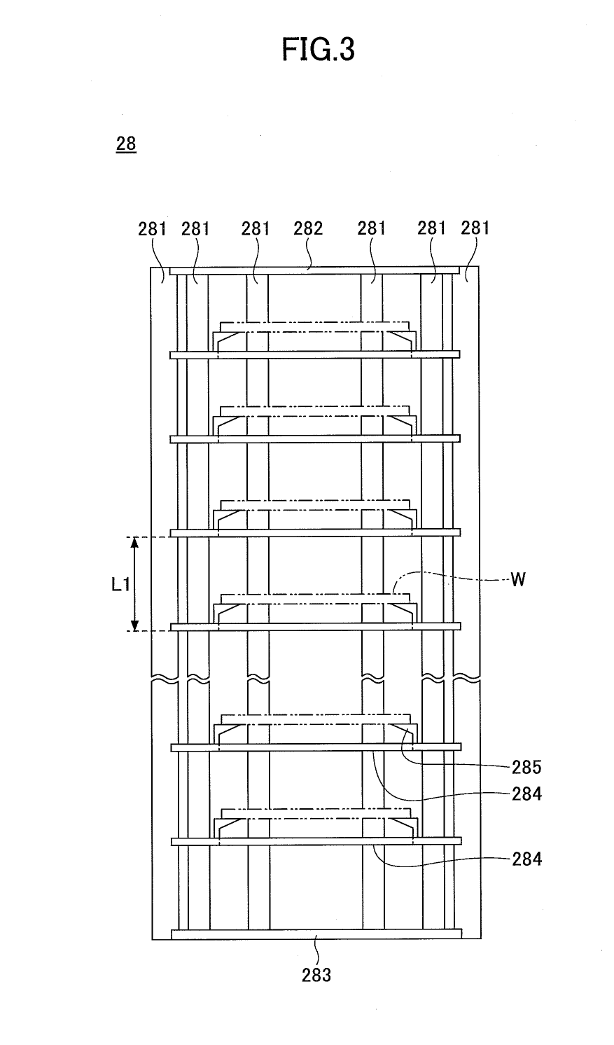

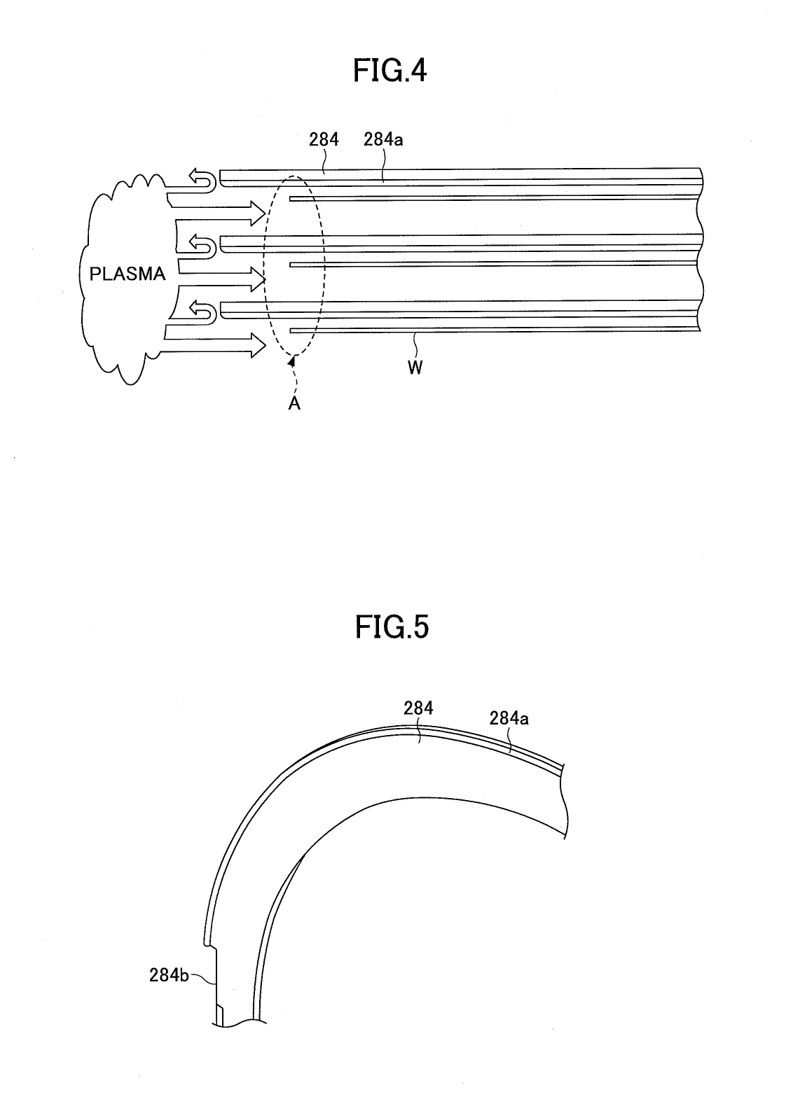

Next, the wafer boat 28 to be housed in the process chamber 24 is described in detail. FIG. 3 is a drawing illustrating an example of the wafer boat 28. FIG. 4 is a schematic side view of an exemplary ring-shaped part 284. FIG. 5 is a schematic perspective view of the ring-shaped part 284. More specifically, FIG. 5 is an enlarged view of a part of the ring-shaped part 284 seen from a process surface of the wafer W to be processed.

The wafer boat 28 is comprised of a heat-resistant material such as quartz and includes columns 281 (in this example, six columns 281) as illustrated in FIG. 3. The upper ends of the columns 281 are fixed to a top plate 282, and the lower ends of the columns 281 are fixed to a bottom plate 283.

Assuming that each of the top plate 282 and the bottom plate 283 is virtually divided into two substantially-semicircular areas (first and second semicircular areas), the columns 281 are arranged at predetermined intervals in the first semicircular area of each of the top plate 282 and the bottom plate 283. With this configuration, the wafers W can be carried into and out of the wafer boat 28 from the side of the second semicircular area facing the first semicircular area where the columns 281 are arranged. In the example of FIG. 3, six columns 281 are arranged in a semicircle at substantially the same interval. However, the number of the columns 281 and the interval at which the columns 281 are arranged are not limited to this example.

Also in FIG. 3, multiple ring-shaped parts 284 are attached in a horizontal position to the columns 281, and are arranged at a pitch L1 in the longitudinal direction of the columns 281.

As illustrated by FIGS. 4 and 5, each ring-shaped part 284 includes a protrusion 284a that is formed along the outer periphery of a lower surface of the ring-shaped part 284 facing the process surface of the wafer W and protrudes downward (toward the process surface of the wafer W), and also includes indentations 284b that are formed in parts of the outer edge of the ring-shaped part 284 and indented in the radial direction of the ring-shaped part 284. The ring-shaped part 284 is welded to the columns 281 such that the indentations 284b are aligned with the columns 281.

As illustrated in FIGS. 3 and 4, the outside diameter of the ring-shaped part 284 is greater than the outside diameter of the wafer W. Claws 285 (in this example, three claws 285) are provided on the upper surface of the ring-shaped part 284. The claws 285 protrude upward from the inner periphery of the upper surface, and also protrude inward in the radial direction of the ring-shaped part 284. The periphery of the lower surface of the wafer W is placed on tips of the claws 285. The claws 285 are positioned such that the wafer W can be supported by three points. With the above configuration, the wafers W and the ring-shaped parts 284 are spaced apart and arranged alternately in the longitudinal direction of the wafer boat 28.

In FIG. 3, as described above, the wafers W are placed on the claws 285 formed on the ring-shaped parts 284 such that the wafers W and the ring-shaped parts 284 are spaced apart and arranged alternately in the longitudinal direction of the wafer boat 28. However, the present invention is not limited to this configuration. For example, grooves may be formed in the wafer boat 28, and the wafers W may be placed in the grooves such that the wafers W and the ring-shaped parts 284 are spaced apart and arranged alternately in the longitudinal direction of the wafer boat 28.

### Substrate Processing Method

Next, an exemplary substrate processing method using the substrate processing apparatus 1 is described. In the exemplary substrate processing method, a plasma atomic layer deposition (ALD) process is performed at near room temperature using the substrate processing apparatus 1 to form a silicon dioxide (SiO₂) film on the process surface of each of the wafers W. In this case, an oxygen gas is used as the first gas to be activated by plasma, and a silane gas is used as the second gas. The SiO₂ film is formed on each of the wafers W by alternately supplying the silane gas and the oxygen gas and activating the oxygen gas by plasma. However, any other substrate processing method may be performed by the substrate processing apparatus 1. For example, a different type of film may be formed on the wafers W. Also, although a plasma ALD process is described in this example, the substrate processing apparatus 1 may also be used to perform other types of substrate processing using plasma such as a plasma chemical vapor deposition (CVD) process, a plasma modification process, a plasma oxidation diffusion process, a plasma sputtering process, and a plasma nitridation process.

First, the wafer boat 28 housing, for example, 50 to 150 wafers W with a diameter of 300 mm is moved upward and loaded into the process chamber 24 that is set at a room temperature of about 23 to 27° C. Next, the lower-end opening of the process chamber 24 is closed by the lid 34 to seal the process chamber 24.

Then, the process chamber 24 is evacuated to a predetermined process pressure, and the oxygen gas and the silane gas are supplied alternately and intermittently into the process chamber 24 from the first gas supply unit 46 and the second gas supply unit 48. Also, during at least a part of the entire time period when the oxygen gas is supplied, the high-frequency power supply 66 is turned on to form plasma in the plasma formation box 62 of the activation unit 58. As a result, an SiO₂ film is formed on the process surface of each of the wafers W held in the wafer boat 28 that is being rotated.

More specifically, the oxygen gas is discharged in the horizontal direction from the gas discharge holes 50A of the first gas nozzle 50, the silane gas is discharged in the horizontal direction from the gas discharge holes 52A of the second gas nozzle 52, and the oxygen gas and the silane gas react with each other on the surface of the wafer W to form the SiO₂ film. In this process, the gases are not continuously supplied, and are supplied at different timings. That is, the gases are alternately and intermittently supplied with an interval (purge period) between the different timings, and one layer of the SiO₂ film is formed on the wafer W each time this supply cycle is repeated. When the oxygen gas is supplied, the high-frequency power 66 is turned on to form plasma. The oxygen gas is activated by the plasma and as a result, active species are generated and the reaction (decomposition) is accelerated. The output level of the high-frequency power supply 66 for this process may be, for example, between 50 W and 3 kW.

### Effects

Effects of the wafer boat 28 and the substrate processing apparatus 1 of the present embodiment are described below.

The wafer boat 28 of the present embodiment can hold a stack of wafers W and is used to perform plasma processing on the wafers. The wafer boat 28 includes the ring-shaped parts 284. Each of the ring-shaped parts 284 is provided between adjacent wafers W, and includes the protrusion 284a that is formed along the outer periphery of the lower surface of the ring-shaped part 284. With this configuration, a part of the first gas discharged from the gas discharge holes 50A of the first gas nozzle 50 and activated by the activation unit 58 is prevented by the protrusion 284a of the ring-shaped part 284 from reaching the wafer W.

More specifically, the first gas ejected from the gas ejection holes 50A of the first gas, nozzle 50 while the high-frequency power supply 66 is turned on is activated in the plasma formation box 62 to form active species such as ion components and radical components, and diffuses and flows toward the center of the process chamber 24. Here, if the ion components reach the wafer W, the ion components cause a film formed on the wafer W to shrink. As a result, the thickness of the film in the outer periphery (indicated by a dotted line “A” in FIG. 4) of the wafer W, to which the ion components are more likely to reach, becomes smaller than the thickness of the film in the central area of the wafer W.

With the wafer boat 28 of the present embodiment, however, many of the ion components are prevented from reaching the wafer W by the protrusion 284a of the ring-shaped part 284. Accordingly, the wafer boat 28 of the present embodiment makes it possible to prevent a film in the outer periphery of the wafer W from shrinking, and thereby makes it possible to improve the in-plane uniformity in film thickness.

Here, the radical components have a long diffusion length and therefore can sufficiently reach the wafer W even when the protrusion 284a is provided in the ring-shaped part 284. Accordingly, even with the wafer boat 28 of the present embodiment, a film can be formed with the radical components on the surface of the wafer W.

The substrate processing apparatus 1 of the present embodiment includes the wafer boat 28 and therefore can improve the in-plane uniformity in film thickness.

### EXAMPLES

An SiO₂ film was formed on silicon wafers with a diameter of 300 mm by using the wafer boat 28 of the present embodiment (this experiment is hereafter referred to as a “present example”). Also, an SiO₂ film was formed on silicon wafers with a diameter of 300 mm by using a wafer boat including ring-shaped parts that do not have the protrusion 284a described above (this experiment is hereafter referred to as a “comparative example”).

In each of the present example and the comparative example, after forming the SiO₂ film on the silicon wafers, the thickness of the SiO₂ film formed on each of silicon wafers placed in the uppermost position, the middle position, and the lowermost position in the wafer boat was measured.

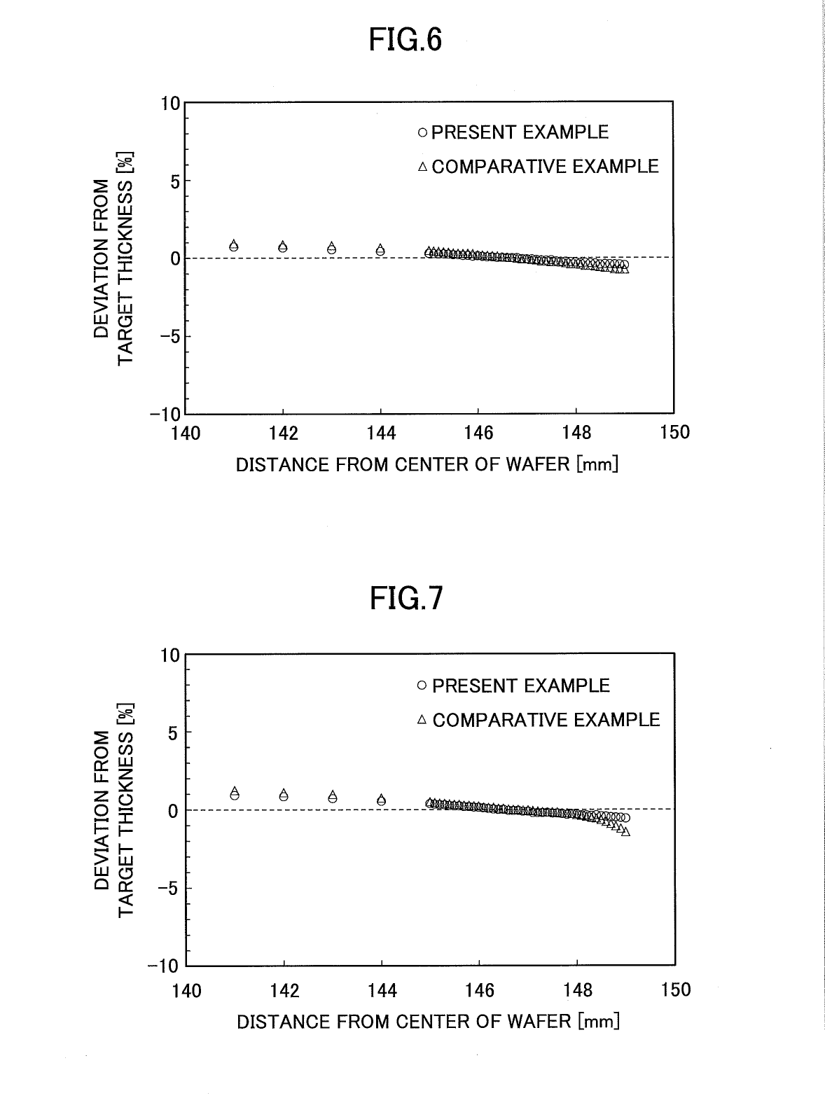

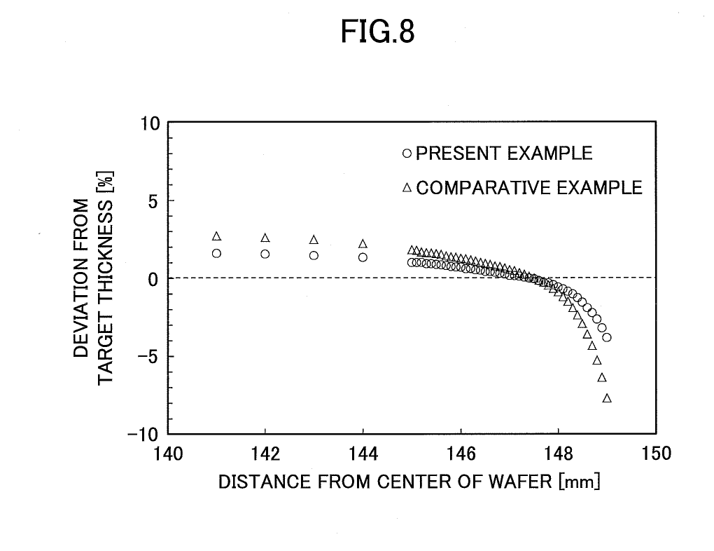

FIGS. 6 through 8 are graphs illustrating measurement results of the thickness of the SiO₂ film formed on the silicon wafers placed in the uppermost position, the middle position, and the lowermost position in the wafer boat. In FIGS. 6 through 8, the vertical axis indicates a deviation (%) from a target thickness, and the horizontal axis indicates a distance (mm) from the center of the silicon wafer. Also in FIGS. 6 through 8, circles “◯” indicate measurement results in the present example, and triangles “Δ” indicate measurement results in the comparative example.

As indicated by FIGS. 6 through 8, at any of the uppermost position, the middle position, and the lowermost position in the wafer boat, the deviation from the target thickness in the outer periphery of the silicon wafer measured in the present example is less than the deviation from the target thickness in the outer periphery of the silicon wafer measured in the comparative example. Thus, it was confirmed that the in-plane uniformity in film thickness can be improved by using the wafer boat 28 of the present embodiment.

A substrate holder and a substrate processing apparatus according to the embodiments are described above. However, the present invention is not limited to the specifically disclosed embodiments, and variations and modifications may be made without departing from the scope of the present invention.

1. A substrate holder for holding a stack of substrates to be plasma-processed, the substrate holder comprising:
a ring-shaped part to be placed between adjacent substrates each of which includes a process surface to be plasma-processed and a non-process surface opposite from the process surface,
wherein the ring-shaped part includes a facing surface that faces the process surface of one of the adjacent substrates, and a protrusion that is formed along an outer periphery of the facing surface and protrudes toward the process surface of the one of the adjacent substrates.

2. The substrate holder as claimed in claim 1, wherein an outside diameter of the ring-shaped part is greater than an outside diameter of the substrates.

3. The substrate holder as claimed in claim 1, wherein the ring-shaped part further includes claws that support the non-process surface of another one of the adjacent substrates.

4. A substrate processing apparatus, comprising:
a substrate holder that holds a stack of substrates to be plasma-processed;
a process chamber that houses the substrate holder;
a gas supply unit that is disposed in the process chamber along a longitudinal direction of the process chamber and supplies a process gas to the substrate holder;
an activation unit that is disposed in the process chamber along the longitudinal direction of the process chamber and activates the process gas,
wherein the substrate holder includes a ring-shaped part to be placed between adjacent substrates each of which includes a process surface to be plasma-processed and a non-process surface opposite from the process surface; and
wherein the ring-shaped part includes a facing surface that faces the process surface of one of the adjacent substrates, and a protrusion that is formed along an outer periphery of the facing surface and protrudes toward the process surface of the one of the adjacent substrates.
